(19) United States
(12) Patent Application Publication
(10) Pub. No.: US 2013/0026660 A1
(43) Pub. Date: Jan. 31, 2013

(54) LIQUID EPOXY RESIN COMPOSITION FOR SEMICONDUCTOR ENCAPSULATION, AND SEMICONDUCTOR DEVICE USING THE SAME

(71) Applicants: Pawel CZUBAROW, Waltham, MA (US); Osamu Suzuki, Niigata-shi (JP); Toshiyuki Sato, Niigata-shi (JP); Kazuyoshi Yamada, Niigata-shi (JP); Kaori Matsumura, Niigata-shi (JP)

(72) Inventors: Pawel CZUBAROW, Waltham, MA (US); Osamu Suzuki, Niigata-shi (JP); Toshiyuki Sato, Niigata-shi (JP); Kazuyoshi Yamada, Niigata-shi (JP); Kaori Matsumura, Niigata-shi (JP)

(73) Assignee: NAMICS CORPORATION, Niigata-shi (JP)

(21) Appl. No.: 13/193,822

(22) Filed: Jul. 29, 2011

(51) Int. Cl. H01L 23/28; C08K 5/3445; C08L 63/10

(52) U.S. Cl. 257/788; 523/461; 257/E23.116

(57) ABSTRACT

A liquid epoxy resin composition for semiconductor encapsulation comprising: (A) an epoxy resin, (B) an imidazole compound, and (C) a maleimide compound, a semiconductor device encapsulated by the liquid epoxy resin composition, and an assembly in which a cured material of the liquid epoxy resin is positioned between a printed circuit substrate and a semiconductor die.

The liquid epoxy resin composition provides a cured material that has an excellent adhesiveness to a semiconductor chip surface and has an excellent moisture resistance.

### TECHNICAL FIELD

The present invention relates to a liquid epoxy resin composition for semiconductor encapsulation and a semiconductor device using the same.

### BACKGROUND ART

The electronic industry has sustained decades of continual reduction of the dimensional scale of integrated circuit features. At the same time, the dimensional scales of both the transistors in the integrated circuits and the electrical connections to the semiconductor chip have also been reduced. The reduction of the scale of transistors allowed more functionality to be integrated into a single chip. More chip functionality provides for the plethora of functionality found in modern electronic devices such as smartphones that can play music, play videos, capture images and communicate using a variety of wireless protocols.

More functionality also calls for more electrical connections into the semiconductor chip and into a package in which it is contained. A semiconductor is typically provided in a package which is sold to original equipment manufacturer (OEM) customers who mount the package on their printed circuit boards (PCB). Alternatively, semiconductor chips without packages are mounted directly on PCBs. The latter attracts attention, since it is advantageous in terms of an increase in electric connection and a decrease in cost.

In order to provide mechanical reinforcement between the semiconductor chip and the substrate on which the chip is placed, an underfill material is usually placed. A liquid epoxy resin composition used for existing underfill comprises an epoxy resin and may include other ingredients such as a silica filler, a silane coupling agent and a fluorinated or silicone defoamer. The liquid epoxy resin composition is cured after the space between the semiconductor chip and the substrate on which the chip is placed is filled with it.

As stated above, semiconductor chips are used in portable electronic gadgets such as smartphones. Such portable electronic gadgets, however, are not always treated as sensitive electronic devices, and it is to be expected that they may be dropped, abused or subjected to mechanical shocks. In addition, they might be used in very bad environmental conditions, such as hot and humid conditions. Against these backgrounds, as for the liquid epoxy resin composition used for underfill, it is demanded that the cured material thereof has an excellent adhesiveness to the semiconductor chip surface and has an excellent moisture resistance.

In recent years, liquid epoxy resin compositions that have an excellent adhesiveness to semiconductor chip surfaces have been proposed (for instance, see patent documents 1 and 2).

### PRIOR ART DOCUMENTS

### Patent Documents

[Patent Document 1] JP-A-2010-280804 (non-examined patent publication)
[Patent Document 2] JP-A-2010-77234 (non-examined patent publication)

### SUMMARY OF THE INVENTION

### Problems to be Solved by the Invention

Against a background of the improvement of electronic device functionality as discussed hereinabove, the demand level for a liquid epoxy resin composition for semiconductor encapsulation has increased. An object of the present invention is to provide a liquid epoxy resin composition for semiconductor encapsulation that can provide a cured material having an excellent adhesiveness to a semiconductor chip surface and having an excellent moisture resistance, and a semiconductor device encapsulated by the liquid epoxy resin.

### Means for Solving Problems

As a result of wholehearted experimentations, the present inventors discovered that the above object can be accomplished by a liquid epoxy resin composition for semiconductor encapsulation made by blending an imidazole compound and a maleimide compound with an epoxy resin.

In the liquid epoxy resin composition for semiconductor encapsulation that contains an epoxy resin and an imidazole compound, the imidazole compound functions as a curing catalyst of epoxy resins, as well as acts on the semiconductor chip surface and improves the adhesiveness between said surface and the cured material of the resin composition. The following are considered as the mechanisms, although the mechanisms are not necessarily certain (see scheme 1).
The semiconductor chip typically has the polyimide passivation coating or the like on the surface thereof.
When the imidazole compound exists, the nitrogen atom of the imidazole compound attacks the carbonyl moiety of the imide ring and opens the imide ring.
At the same time, the nitrogen atom of the imidazole compound forms a bond with the carbon atom of the carbonyl moiety of the opened imide ring. This carbon atom and the epoxy resin react and the imidazole compound is eliminated, after that the bond is formed between the epoxy resin and the polyimide passivation coating.
This bond affects the adhesiveness between the semiconductor chip surface and the cured material.

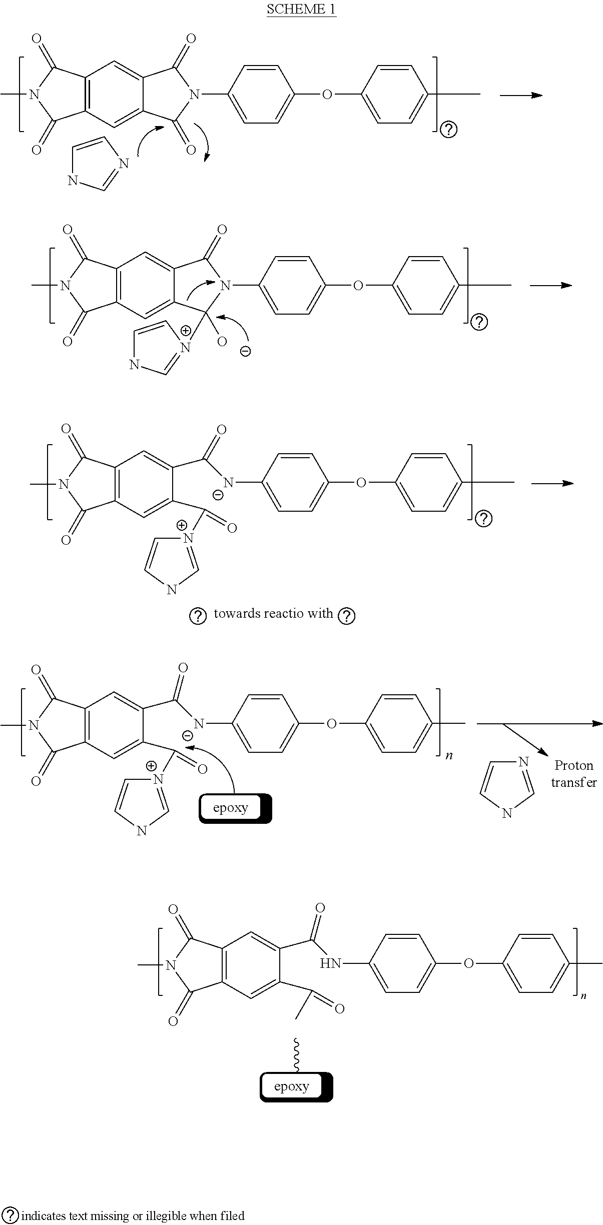

The present inventors discussed that the above-mentioned cured material, however, is deteriorated in the presence of moisture and the adhesiveness becomes diminished. The following are considered as the mechanisms, although the mechanisms are not necessarily certain (see scheme 2).
The imidazole compound remaining in the cured material attacks again the carbon atom of the carbonyl moiety of the opened imide ring of the polyimide passivation coating.
With this step, the epoxy resin is eliminated and the bond is formed between the carbon atom and the imidazole compound.
When moisture exists, in turn, the moisture attacks the carbon atom and eliminates the imidazole compound.
This imidazole compound attacks the carbon atom of the carbonyl moiety of the opened imide ring, and with this step, the epoxy resin is eliminated and the adhesiveness decreases.

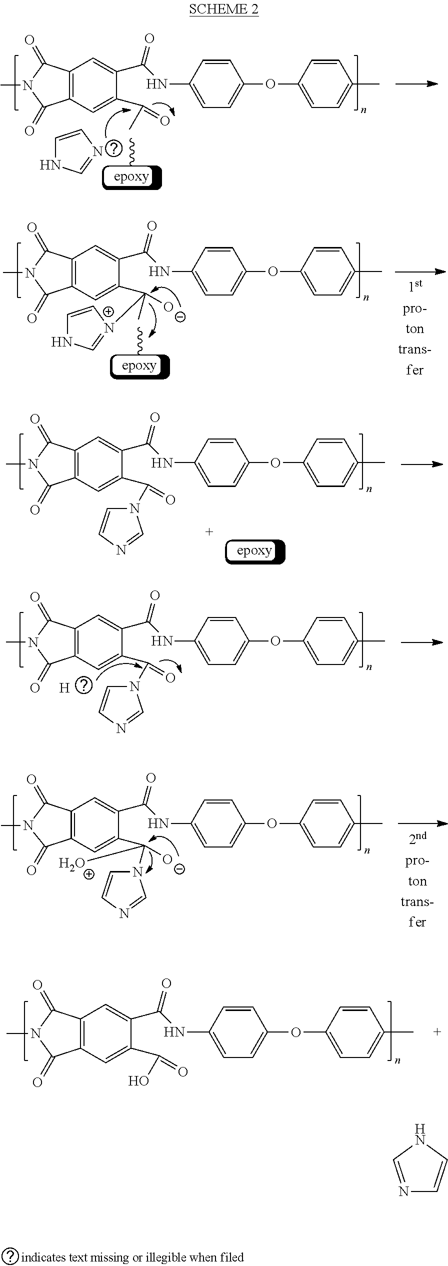

The present inventors discovered that the adhesiveness between the semiconductor chip surface and the cured material of resin composition are improved and the degradation of adhesiveness is reduced even in the presence of moisture by the liquid epoxy resin composition for semiconductor encapsulation made by blending an imidazole compound and a maleimide compound with an epoxy resin. The mechanisms are not necessarily certain. It is, however, considered that since the free imidazole compound in the cured material is trapped by the maleimide compound, the carbon atom of the carbonyl moiety of the opened imide ring of the polyimide passivation coating is attacked again and the elimination of epoxy resin is prevented.

The present invention 1 relates to a liquid epoxy resin composition for semiconductor encapsulation comprising:

(A) at least one epoxy resin,
(B) at least one imidazole compound, and
(C) at least one maleimide compound.

The present invention 2 relates to the liquid epoxy resin composition for semiconductor encapsulation of the present invention 1, wherein the imidazole compound is in an amount of 0.01 to 10 parts by weight and the maleimide compound is in an amount of 0.1 to 16 parts by weight, based on 100 parts by weight of the epoxy resin.

The present invention 3 relates to the liquid epoxy resin composition for semiconductor encapsulation of the present invention 1, wherein the maleimide compound is at least one compound selected from the group consisting of a monomaleimide compound and a bismaleimide compound.

The present invention 4 relates to the liquid epoxy resin composition for semiconductor encapsulation of the present invention 1, further comprising at least one curing agent (D) selected from the group consisting of a phenolic resin and an acid anhydride.

The present invention 5 relates to the liquid epoxy resin composition for semiconductor encapsulation of the present invention 1, further comprising at least one inorganic filler.

The present invention 6 relates to the liquid epoxy composition for semiconductor encapsulation of the present invention 2, wherein the maleimide compound is at least one compound selected from the group consisting of a monomaleimide compound and a bismaleimide compound.

The present invention 7 relates to the liquid epoxy composition for semiconductor encapsulation of the present invention 2, which further comprises at least one curing agent (D) selected from the group consisting of a phenolic resin and an acid anhydride.

The present invention 8 relates to the liquid epoxy composition for semiconductor encapsulation of the present invention 3, which further comprises at least one curing agent (D) selected from the group consisting of a phenolic resin and an acid anhydride.

The present invention 9 relates to the liquid epoxy composition for semiconductor encapsulation of the present invention 6, which further comprises at least one curing agent (D) selected from the group consisting of a phenolic resin and an acid anhydride.

The present invention 10 relates to a flip chip semiconductor device comprising a substrate and a semiconductor, wherein the semiconductor is secured to the substrate by a liquid epoxy resin composition of the present invention 1.

The present invention 11 relates to the flip chip semiconductor device of the present invention 10, wherein the imidazole compound is in an amount of 0.01 to 10 parts by weight and the maleimide compound is in an amount of 0.1 to 16 parts by weight, based on 100 parts by weight of the epoxy resin.

The present invention 12 relates to the flip chip semiconductor device of the present invention 10, wherein the maleimide compound is at least one compound selected from the group consisting of a monomaleimide compound and a bismaleimide compound.

The present invention 13 relates to the flip chip semiconductor device of the present invention 10, wherein the liquid epoxy resin composition for semiconductor encapsulation further comprises at least one curing agent (D) selected from the group consisting of a phenolic resin and an acid anhydride.

The present invention 14 relates to the flip chip semiconductor device of the present invention 10, wherein the liquid epoxy resin composition for semiconductor encapsulation further comprises at least one inorganic filler.

The present invention 15 relates to the flip chip semiconductor device of the present invention 11, wherein the maleimide compound is at least one compound selected from the group consisting of a monomaleimide compound and a bismaleimide compound.

The present invention 16 relates to the flip chip semiconductor device of the present invention 11, wherein the liquid epoxy resin composition for semiconductor encapsulation further comprises at least one curing agent (D) selected from the group consisting of a phenolic resin and an acid anhydride.

The present invention 17 relates to the flip chip semiconductor device of the present invention 11, wherein the liquid epoxy resin composition for semiconductor encapsulation further comprises at least one inorganic filler.

The present invention 18 relates to an assembly comprising:

a printed circuit substrate;
a semiconductor die; and
a cured material of a liquid epoxy resin composition of the present invention 1, the cured material is positioned between the printed circuit substrate and the semiconductor die, so that the semiconductor die is secured to the printed circuit substrate.

### Inorganic Filler.

The present invention 19 relates to the assembly of the present invention 18, wherein the imidazole compound is in an amount of 0.01 to 10 parts by weight and the maleimide compound is in an amount of 0.1 to 16 parts by weight, based on 100 parts by weight of the epoxy resin.

The present invention 20 relates to the assembly of the present invention 18, wherein the maleimide compound is at least one compound selected from the group consisting of a monomaleimide compound and a bismaleimide compound.

### Effects of the Invention

The liquid epoxy resin composition for semiconductor encapsulation of the present invention can provide a cured material that has excellent adhesiveness to a semiconductor chip surface and has excellent moisture resistance. The heretofore problem that a delamination occurs between an underfill and a semiconductor chip under the physical impact and the high temperature humidity can be resolved by using the liquid epoxy resin composition for semiconductor encapsulation of the present invention as an underfill.

### BRIEF DESCRIPTION OF THE DRAWINGS

FIG. 1 is a schematic drawing of the sample used in the shear bonding strength test 1 of the Examples.

FIG. 2 is a schematic drawing of the sample used in the shear bonding strength test 2 of the Examples.

FIG. 3 is a schematic drawing of a flip chip type semiconductor device.

### BEST MODE TO CARRYOUT THE INVENTION

The present invention 1 relates to a liquid epoxy resin composition for semiconductor encapsulation comprising (A) an epoxy resin, (B) an imidazole compound and (C) a maleimide compound. As used herein, “liquid state at normal temperature” means having fluidity at 10 to 35 degrees C.

### (A) Epoxy Resin

The epoxy resin (A) in the present invention is not specifically limited so long as it is an epoxy compound that has two or more epoxy groups in one molecule. The epoxy resin is preferably in a liquid state at a normal temperature, however, even if it is a solid state at a normal temperature, it can be used in a liquid state by dissolving it in other liquid epoxy resins or a diluent.

As the epoxy resin (A), a bisphenol A type epoxy resin, a brominated bisphenol A type epoxy resin, a bisphenol F type epoxy resin, a biphenyl type epoxy resin, a novolac type epoxy resin, an alicyclic epoxy resin, a naphthalene type epoxy resin, an ether series or polyether series epoxy resin, an oxirane ring-containing polybutadiene, a silicone epoxy copolymer resin and the like may be mentioned.

As an epoxy resin in a liquid state, a bisphenol A type epoxy resin having an average molecular weight of about 400 or less; a branched polyfunctional bisphenol A type epoxy resin such as p-glycidyloxyphenyl dimethyltolylbisphenol A diglycidyl ether; a bisphenol F type epoxy resin; a phenol novolac type epoxy resin having an average molecular weight of about 570 or less; an alicyclic epoxy resin such as vinyl(3,4-cyclohexene)dioxide, methyl 3,4-epoxycyclohexylcarboxylate (3,4-epoxycyclohexyl), bis(3,4-epoxy-6-methylcyclohexylmethyl) adipate and 2-(3,4-epoxycyclohexyl)-5,1-spiro(3,4-epoxycyclohexyl)-m-dioxane; a biphenyl type epoxy resin such as 3,3′,5,5′-tetramethyl-4,4′-diglycidyloxybiphenyl; a glycidyl ester type epoxy resin such as diglycidyl hexahydrophthalate, diglycidyl 3-methylhexahydro phthalate and diglycidyl hexahydroterephthalate; a glycidylamine type epoxy resin such as diglycidylaniline, diglycidyltoluidine, triglycidyl-p-aminophenol, tetraglycidyl-m-xylylene diamine, tetraglycidylbis(aminomethyl)cyclohexane; a hidantoin type epoxy resin such as 1,3-diglycidyl-5-methyl-5-ethylhidantoin; and a naphthalene ring-containing epoxy resin may be mentioned. Also, an epoxy resin having silicone skeletone such as 1,3-bis(3-glycidoxy-propyl)-1,1,3,3-tetramethyldisiloxane may be used. Moreover, a diepoxide compound such as (poly)ethylene glycol diglycidyl ether, (poly)propylene glycol diglycidyl ether, butanediol diglycidyl ether and neopentyl glycol diglycidyl ether; and a triepoxide compound such as trimethylolpropane triglycidyl ether and glycerin triglycidyl ether may be mentioned.

It is also possible to use a solid state or ultra-high viscosity epoxy resin at a normal temperature together. As such an epoxy resin, a bisphenol A type epoxy resin, novolac epoxy resin and tetrabromobisphenol A type epoxy resin, each of which has a higher molecular weight, may be mentioned. These epoxy resins may be used in combination with the epoxy resin which is in a liquid state at a normal temperature and/or a diluent to control the viscosity.

As an epoxy resin having a low viscosity at a normal temperature, a diepoxide compound such as (poly)ethyleneglycol diglycidyl ether, (poly)propylenglycol diglycidyl ether, butanediol glycidyl ether and neopentylglycol diglycidyl ether; and a triepoxide compound such as trimethylolpropane triglycidyl ether and glycerin triglycidyl ether may be mentioned.

A diluent may be a non-reactive diluent or a reactive diluent, however, a reactive diluent is preferable. As used herein, a reactive diluent means a compound having an epoxy group and having a low viscosity at a normal temperature, depending on the purposes, which may further have a polymerizable functional group other than the epoxy group, for example, an alkenyl group such as vinyl and allyl; an unsaturated carboxylic acid residue such as acryloyl and methacryloyl. As such a reactive diluent, a monoepoxide compound such as n-butylglycidyl ether, 2-ethylhexyl glycidyl ether, phenyl gylcidyl ether, cresyl glycidyl ether, p-s-butylphenyl glycidyl ether, styrene oxide and a-pinene oxide; a monoepoxide compound having other functional group such as allyl glycidyl ether, glycidyl methacrylate, and 1-vinyl-3,4-epoxycyclohexane may be mentioned.

The epoxy resin may be used alone or in combination of two or more kinds. It is preferred that the epoxy resin itself is in a liquid state at a normal temperature, and above all, preferred are a liquid state bisphenol type epoxy resin, a liquid state aminophenol type epoxy resin, a silicone-modified epoxy resin and a naphthalene type epoxy resin. More preferably mentioned are a liquid state bisphenol A type epoxy resin, a liquid state bisphenol F type epoxy resin, a p-aminophenol type liquid state epoxy resin and 1,3-bis(3-glycid-oxypropyl)tetramethyl disiloxane.

### (B) Imidazole Compound

As the imidazole compound (B) in the present invention, it is not specifically limited so long as it functions as a curing catalyst of epoxy resins, imidazole, 2-methylimidazole, 2-ethylimidazole, 2-isopropylimidazole, 2-undecylimidazole, 2-dodecylimidazole, 2-phenylimidazole, 2-ethyl-4-methyl-imidazole, 2-benzylimidazole, 2,4,5-trimethylimidazole and the like may be mentioned.

As the imidazole compound (B), an epoxy adduct with an imidazole compound, a urea adduct with an imidazole compound and a compound in which an isocyanate compound is added to a hydroxyl group of an epoxy adduct with an imidazole compound may also be used.

The epoxy adduct can be obtained by reacting an imidazole compound with an epoxy compound. After that, an isocyanate compound may also be subjected to addition reaction to the hydroxyl group of the epoxy adduct.

As the epoxy compound, there may be mentioned 1,2-epoxybutane, 1,2-epoxyhexane, 1,2-epoxyoctane, styreneoxide, n-butyl glycidyl ether, hexyl glycidyl ether, phenyl glycidyl ether, glycidyl acetate, glycidyl butyrate, glycidyl hexoate, glycidyl benzoate and the like.

As the isocyanate compound, there may be mentioned phenyl isocyanate, p-methyl phenyl isocyanate, o-methyl phenyl isocyanate, p-methoxyphenyl isocyanate, 2,4-dimethylphenyl isocyanate, o-chlorophenyl isocyanate, p-chlorophenyl isocyanate, methyl isocyanate, ethyl isocyanate, propyl isocyanate, butyl isocyanate, hexyl isocyanate and the like.

The urea adduct can be obtained by reacting an imidazole compound, a urea compound, and optionally an isocyanate compound. The imidazole compound and the isocyanate compound include those as exemplified above. As the urea compound, there may be mentioned urea, thiourea and the like.

The material in which isocyanate compound is subjected to addition reaction with a hydroxyl group of an epoxy adduct also contains a so-called microcapsulated imidazole and, for example, is available as NOVACURE HX-3088 and NOVACURE HX-3722 (each available from Asahi Kasei Chemicals Corp., trade name), and the like.

In addition, the imidazole compound (B) may be used in the form of an inclusion compound that contains an imidazole compound and an acid. As the acid, isophthalic acid or derivatives thereof (an isophthalic acid having substituent groups such as alkyl group, aryl group and the like) may be mentioned. The inclusion compound can be obtained by dissolving or suspending the above-mentioned imidazole compound and acid in a solvent, and heating the resultant. As such an inclusion compound, the one described in JP-A-2007-39449 may be used.

Moreover, the imidazole compound (B) may be used in the form of an inclusion compound in which an imidazole compound is a guest and a carboxylic acid derivative is a host. As the carboxylic acid derivatives, tetrakisphenyl compounds such as tetrakis(4-hydroxyphenyl)ethane and a tetrakis(4-hydroxyphenyl)ethane tetramethyl ester may be mentioned. As such an inclusion compound, the one described in JP-A-Hei 05-201902 may be used.

The imidazole compound (B) may be used alone or in combination of two or more kinds.

### (C) Maleimide Compound

The maleimide compound (C) in the present invention is a compound that has one or more maleimide structures, among these, monomaleimide compounds and bismaleimide compounds are preferable.

As the monomaleimide compound, there may be mentioned a maleimide compound represented by the formula (1):

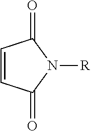

wherein R is a hydrogen atom or -Ar1-R1, Ar1 is a bivalent aromatic residue having 6 to 20 carbon atoms, and R1 is a hydrogen atom or a hydroxyl group.

In the formula (1), R is a hydrogen atom or -Ar1-R1. Ar1 is a bivalent aromatic residue having 6 to 20 carbon atoms, for example, there may be mentioned a phenylene group which may be unsubstituted or substituted with a straight or branched alkyl group having 1 to 6 carbon atoms (preferably, a methyl group and an ethyl group). R1 is a hydrogen atom or a hydroxyl group.

As a maleimide compound represented by the formula (1), maleimide, N-phenylmaleimide (PMI), N-(2-methylphenyl)maleimide, N-(2-ethylphenyl)maleimide, N-(2,5-dimethylphenyl)maleimide, N-(4-hydroxyphenyl)maleimide (HPMI), N-(2-methyl-4-hydroxyphenyl)maleimide, N-(2-ethyl-4-hydroxyphenyl)maleimide, N-(2,5-dimethyl-4-hydroxyphenyl)maleimide may be mentioned. A compound having a molecular weight of 90 to 1000 is preferred in terms of the fact that it is easy to provide the appropriate range of viscosity of the composition and the injection property in combination with the flip chip bonding and the like is excellent, and especially preferred are maleimide, N-phenylmaleimide (PMI) and N-(4-hydroxyphenyl)maleimide (HPMI).

As the bismaleimide compound, there may be mentioned a maleimide compound represented by the formula (2):

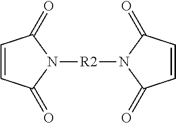

wherein R2 is a bivalent organic residue.

In the formula (2), R2 is a bivalent organic residue, there may be mentioned a bivalent aliphatic hydrocarbon group having 1 to 10 carbon atoms (for example, a straight or a branched alkyl group having 1 to 6 carbon atoms), a bivalent alicyclic hydrocarbon group having 3 to 20 carbon atoms (for example, a cycloalkylene group having 3 to 20 carbon atoms), a bivalent aromatic hydrocarbon group having 6 to 20 carbon atoms (for example, a phenylene group which may be substituted with a straight or a branched alkyl group having 1 to 6 carbon atoms), or a group which is the combination of two or more these groups. These groups may have hetero atoms (oxygen atom, sulfur atom, and nitrogen atom).

R2 is a straight or a branched alkylene group having 1 to 6 carbon atoms (preferably, a methylene group or an ethylene group) or the groups:

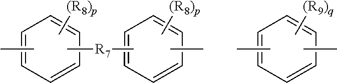

in which
R₇ is single bond, CH₂, O, S, SO₂ or C(CH₃)₂, preferably CH₂; R₈ is independently a hydroxyl group or a straight or branched alkyl group having 1 to 6 carbon atoms, preferably a methyl group or an ethyl group; p is an integer of 0 to 4, preferably 0, 1 or 2; R₉ is independently a hydroxyl group or a straight or a branched alkyl group having 1 to 6 carbon atoms, preferably a methyl group or an ethyl group; q is an integer of 0 to 4, preferably 0, 1 or 2.

As a maleimide compound represented by the formula (2), N,N′-(4,4′-diphenylmethane)bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6′-bismaleimide-(2,2,4-trimethyl)hexane may be mentioned.

The maleimide compound (C) may be used alone or in combination of two or more kinds.

The imidazole compound (B) may be used in an amount of 0.01 to 10 parts by weight, preferably 0.03 to 9 parts by weight, based on 100 parts by weight of the epoxy resin (A), in terms of obtaining good adhesiveness, moisture resistance and curability.

The maleimide compound (C) may be used in an amount of 0.1 to 16 parts by weight, preferably 0.5 to 13 parts by weight, based on 100 parts by weight of the epoxy resin (A), in terms of obtaining good adhesiveness and a demanded injection property in combination with the flip chip bonding.

(D) Curing Agent Selected from the Group Consisting of Phenol Resins and Acid Anhydrides

The composition of the present invention may further comprise a curing agent selected from the group consisting of phenol resins and acid anhydrides (D). The crack resistance and the moisture resistance are improved by using these curing agents together, and high reliability can be gained. Additionally, when the composition of the present invention is used in combination or the like with the flip-chip bonding, phenolic resins are preferably added.

As the phenolic resin, it is not specifically limited, phenol novolac resin, cresol novolac resin, naphthol-modified phenol resin, dicyclopenadiene-modified phenol resin and p-xylene-modified phenol resin and the like may be mentioned. A phenol novolac resin may be substituted by a substituent such as an allyl group and the like. The formulating ratio of the epoxy resin (A) to the phenolic resin is the ratio in which the number of OH group in the phenol resin is preferably 0.3 to 1.5, more preferably 0.5 to 1.2 per one epoxy group in the epoxy resin. However, it can be used at the rate that is less than 0.3 when using it in combination with an acid anhydride. The phenol resin may be used alone or in combination of two or more kinds.

As the acid anhydride, it is not specifically limited, methyltetrahydrophthalic anhydride, methylhexahydrophthalic anhydride, alkylated tetrahydrophthalic anhydride, hexahydrophthalic anhydride, methylhymic anhydride, dodecenyl succinic anhydride and methylnadic anhydride and the like may be mentioned. The mixing ratio of the epoxy resin to the acid anhydride is the ratio in which the number of acid anhydride groups in the acid anhydride is preferably 0.4 to 1.2, more preferably 0.5 to 1.0 per one epoxy group in the epoxy resin. The acid anhydride may be used alone or in combination of two or more kinds.

### (E) Other Components

An elastomer may be added to the composition of the present invention, in order to relax the stress. As the elastomer, there may be mentioned a butadiene series rubber such as polybutadiene rubber, styrene-butadiene rubber and acrylonitrilebutadiene rubber; polyisoprene rubber; an ethylene propylene series rubber such as an ethylene propylene diene copolymer and an ethylene propylene copolymer; chloroprene rubber; butyl rubber; polynorbornene rubber; silicone rubber; a polar group-containing rubber such as ethylene acrylic rubber, acrylic rubber, propylene oxide rubber and urethane rubber; and a fluorine rubber such as vinylidene fluoride-propylene hexafluoride copolymer and tetrafluoroethylene-propylene copolymer. A solid elastomer can be used and the form is not especially limited. When it is in particulate form, the mean particle size is preferably 10 to 200 nm, more preferably about 30 to 150 nm, more preferably still 80 to 120 nm. As used herein, the mean particle size is a value determined by the dynamic light scattering type particle size distribution meter.

An elastomer which is liquid at the normal temperature may be used. Specifically, there may be mentioned polybutadiene, butadiene acrylonitrile copolymer, polyisoprene, polypropylene oxide and polydiorganosiloxane, each of which has a relatively low average molecular weight (for example, a weight-average molecular weight of less than 8000). Moreover, an elastomer having a functional group that reacts with the epoxy group (for example, carboxyl group) at the end may be used, and it may be taken in any form either in solid form or liquid form.

The elastomer may be used in an amount of 20 parts by weight or less, for example, 0.1 to 15 parts by weight, preferably 1 to 10 parts by weight, based on 100 parts by weight of the total amounts of components (A) to (C), in terms of obtaining good viscosity of the composition, compatibility or dispersibility with the epoxy resin, properties of the cured material. An elastomer may be used alone or in combination of two or more kinds.

A surfactant may be added to the composition of the present invention, in order to obtain good workability. The surfactant may be an anionic surfactant, a cationic surfactant, a nonionic surfactant or an amphoteric surfactant. A nonionic surfactant is preferred for having little influence on electrical properties. As the nonionic surfactant, there may be mentioned a polyoxyalkylene-containing nonionic surfactant such as a polyoxyethylene alkylether, polyoxyethylene alkyl arylether, an alkylallylformaldehyde condensed polyoxyethylene ether, a block polymer having polyoxypropylene as lipophilic group, a polyoxyethyene-polyoxypropylene block copolymer, a polyoxyethylene fatty acid ester, a polyoxyethylene glycerol fatty acid ester, a polyoxyethylene sorbitan fatty acid ester, a polyoxyethylene sorbitol fatty acid ester, a polyoxyethylene fatty acid amide; a siloxane-containing nonionic surfactant such as a polyoxyalkylene-modified polysiloxane; an ester type surfactant such as a glycerol fatty acid ester, a polyglycerol fatty acid ester, a sorbitan fatty acid ester, a propylene glycol fatty acid ester, a sucrose fatty acid ester; a nitrogen-containing type surfactant such as a fatty acid alkanol amide, fluorinated surfactant. In particular, a siloxane-containing nonionic surfactant such as a polyoxyalkylene-modified polysiloxane, fluorinated surfactant are preferred in order to improve an ability for forming a fillet.

The surfactant may be used in an amount of 1 parts by weight or less, for example, 0.05 to 0.5 parts by weight, based on 100 parts by weight of the total amounts of components (A) to (C), in terms of obtaining good viscosity of the composition, compatibility or dispersibility with the epoxy resin, and desirable properties of the cured material. A surfactant may be used alone or in combination of two or more kinds.

An inorganic filler may be added to the composition of the present invention, for the purpose of adjusting the thermal expansion coefficient. As the inorganic filler, there may be mentioned silica, alumina, boron nitride, aluminum nitride, silicon nitride. Silica may be amorphous silica or crystalline silica. Amorphous silica is preferred. The inorganic filler may be surface-treated by a silane coupling agent and the like. An inorganic filler without surface-treatment may be used.

An organic filler may be used in an amount of 80 percent by weight or less, for example, 30 to 70 percent by weight, based on the total amounts of the composition. The inorganic filler may be used alone or in combination of two or more kinds.

A silane coupling agent such as 3-glycidoxypropyl trimethoxy silane, 3-glycidoxypropyl (methyl)dimethoxy silane, 2-(2,3-epoxycyclohexyl)ethyltrimethoxy silane, 3-methacryloxypropyl trimethoxy silane, 3-aminopropyl triethoxy silane, 3-(2-aminoethyl)aminopropyl trimethoxy silane may be added to the composition of the present invention, for the purpose of improving adhesiveness.

A silane coupling agent may be used in an amount of 3 parts by weight or less, for example, 0.03 to 2 parts by weight, based on 100 parts by weight of the total amounts of components (A) to (C). A silane coupling agent may be used alone or in combination of two or more kinds.

A colorant such as carbon black may be added to the composition of the present invention. Since a color of the composition of the present invention changes before and after curing, a progress of curing may be checked by a color-change.

For example, when a phenolic resin is used in the composition of the present invention, its color is white before curing and is brown to red after curing. A colorant is not favorable when utilizing a color-change for checking a progress of curing.

A deformer, an inorganic fiber, a flame retarder, an ion trapping agent, an internal mold releasing agent, a sensitizer, and the like may be added to the composition of the present invention in an amount that does not impair the effects of the present invention.

The process for preparing the composition of the present invention is not specifically limited. The composition of the present invention can be prepared, for example, by mixing raw materials in prescribed amounts using a grinding machine, a pot mill, a triple roll mill, a rotary mixing machine, a biaxial mixer and the like.

The composition of the present invention is in a liquid state at normal temperature, and preferably has a viscosity at 25 degrees C. of 0.1 to 150 Pa·s, more preferably, 0.1 to 100 Pa·s. As used herein, viscosity is a value determined at 25 degrees C. by using an HB type rotary viscometer (50 rpm).

The composition of the present invention is suitable for an underfill to bond a semiconductor chip with a substrate, and is particularly advantageous for an underfill for flip chip bonding. For example, a flip chip type semiconductor device may be obtained by injecting the composition of the present invention between the space of the substrate 408 and the semiconductor chip 402 face-down mounted thereon, followed by curing for encapsulation as shown in FIG. 2. Alternatively, a semiconductor device may be obtained by applying the composition of the present invention to a substrate by using a dispenser and the like; placing a semiconductor chip thereon; and curing by heating for encapsulation.

A semiconductor chip is not specifically limited, and IC, LSI, VLSI and the like may be used. In general, a surface of a semiconductor is covered by a polyimide passivation coating, a nitride coating, an oxide coating and the like, and thus, plasma etching, chemical etching, UV radiation or the like is applied for obtaining good adhesiveness with the underfill material. When using the composition of the present invention, a surface activation treatment as mentioned above is unnecessary to obtaining good adhesiveness. The composition of the present invention may be also used in combination with a semiconductor chip with surface activation treatment.

The substrate is not specifically limited, and a glass-epoxy substrate (e.g., a FR-4 substrate), an aramid substrate, a polyimide substrate, a metal substrate (e.g., a silicon substrate), a ceramic substrate and the like may be used.

### EXAMPLES

In the following, the present invention is explained in detail by referring to Examples, but the present invention is not limited by these.

### (The Preparation of the Composition)

Samples of Examples 1 to 5 and Comparative examples 1 and 2 were prepared with the formulation shown in Table 1 (the unit of the formulation amount is parts by weight) by mixing all components with a roll mill. With regard to the compositions of Examples and Comparative examples, the following tests were carried out. The results are shown in Table 1.

### (Viscosity Measurement)

The viscosity is a value measured at 25 degrees C. by using a HB type rotational viscometer (SC4-14/6R spindle, rotation speed 50 rpm).

### (Injection Property Measurement)

A gap of 50 micrometers was provided on a FR-4 substrate, and the specimen that fixed a glass plate instead of a semiconductor device was prepared. This specimen was put on a hot plate set at 90 degrees C., and the composition of the Examples or Comparative examples was spread on one end side of the glass plate of the width of 10 mm, then the time to fill the gap with the composition was measured.

### (Shear Bond Strength Test 1)

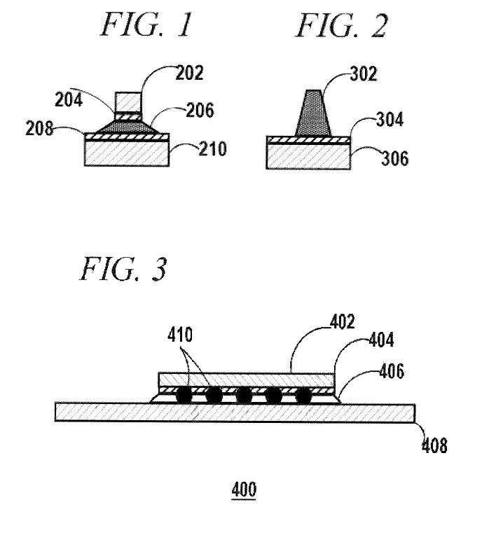

On the aluminum substrate 210 having the polyimide passivation coating 208, the composition of the Examples or Comparative examples is applied in the form of cylinder (a bottom surface diameter of 4.75 mm and height of 100 μm), then the aluminum cylinder 202 (a bottom surface diameter of 6.3 mm, and height of 8 mm) having the polyimide coating 204 was placed thereon and a load of 18 g was applied thereto for 5 min, followed by curing by maintaining 150 degrees C. for one hour (see FIG. 1).

After that, the shear bond strength 1 was measured at a shearing speed of 200 μm/second with a universal testing machine.

The shear bond strength test 1 was also performed with respect to the samples after storing under the conditions of 2 atom, 121 degrees C. at 100% relative humidity for 20 hours.

### (Shear Bond Strength Test 2)

On the aluminum substrate 306 having the polyimide passivation coating 304, the circular truncated cone (a bottom surface diameter of 5 mm, a top surface diameter of 3 mm, and height of 6 mm) was formed with the composition of the Examples or Comparative examples, and the composition was cured by maintaining 150 degrees C. for one hour (see FIG. 1).

After that, the shear bond strength 2 was measured at a shearing speed of 200 μm/second with a universal testing machine.

The shear bond strength test 2 was also performed with respect to the samples after storing under the conditions of 2 atom, 121 degrees C. at 100% relative humidity for 20 hours.

TABLE 1

| | Comp. | | | | | | Comp. | |
|---|---|---|---|---|---|---|---|---|
| | Example 1 | Example 1 | Example 2 | Example 3 | Example 4 | Example 5 | Example 2 | Example 6 |
| (a) Bisphenol F type epoxy resin | 23.3 | 23.3 | 23.3 | 23.3 | 23.3 | 23.3 | 40 | 40 |
| (epoxy equivalent 170) | | | | | | | | |
| (b) Microcapsulated imidazole | 3.5 | 3.5 | 3.5 | 3.5 | 3.5 | 3.5 | 4.6 | 4.6 |
| Epoxy resin | (2.3) | (2.3) | (2.3) | (2.3) | (2.3) | (2.3) | (3.0) | (3.0) |
| Imidazole compound | (1.2) | (1.2) | (1.2) | (1.2) | (1.2) | (1.2) | (1.6) | (1.6) |
| (d) allylated phenol novolac resin | 17.6 | 17.6 | 17.6 | 17.6 | 17.6 | 17.6 | — | — |
| (c-1) N-phenyl maleimide | — | 1 | 1.5 | — | — | — | — | — |
| (c-2) N-hydroxy phenyl maleimide | — | — | — | 1 | 1.5 | 2.0 | — | 1.5 |
| Inorganic filler | 54.2 | 54.2 | 54.2 | 54.2 | 54.2 | 54.2 | 54.2 | 54.2 |
| Silane coupling agent | 0.3 | 0.3 | 0.3 | 0.3 | 0.3 | 0.3 | 0.3 | 0.3 |
| Total | 98.9 | 99.9 | 100.4 | 99.9 | 99.9 | 100.4 | 99.1 | 100.6 |
| Viscosity (Pa · s) | 61 | 46 | 60 | 60 | 70 | 79 | 19 | 39 |
| Injection property (sec) | 580 | 480 | 600 | 600 | 620 | 630 | 220 | 600 |
| Shear bond strength test 1: before PCT test (kgf) | 124.6 | 80.3 | 76.9 | 103.8 | 78.4 | 77.8 | 40 | 65 |
| Shear bond strength test 1: after PCT test (kgf) | 28.7 | 58.8 | 47.7 | 77.3 | 53.5 | 50.6 | 15 | 32 |
| Shear bond strength test 2: before PCT test (kgf) | 84.6 | 81.7 | 69.6 | 73.8 | 67.2 | 55.5 | 0 | 53 |
| Shear bond strength test 2: after PCT test (kgf) | 17.3 | 37.7 | 36.5 | 47.4 | 51.2 | 42.3 | 0 | 25 |
| Color (before curing → after curing | White→ | White→ | White→ | White→ | White→ | White→ | White→ | White→ |
| | Brown | Red | Red | Red | Red | Red | Brown | Red |

PCT test: the sample was stored under the condition of 2 atom, 121 degrees C. at 100% relative humidity for 20 hours before subjecting the shear bond strength test.

The following are (b), (d), and other components used in the Examples.

### (b) Microcapsulated Imidazole

Trade Name: NOVACURE HX-3088 (imidazole content of 35% by weight); manufactured by Asahi Kasei E-materials Corporation

### (d) Allylated Phenol Novolac Resin

Trade Name: MEH 8000H(OH equivalent of 140); manufactured by Meiwa Plastic Industries Ltd.

(Other) Inorganic Filler

Spheroidal Silica Particles having an average particle size of 2 μm (Laser diffraction scattering method, Measuring Device: LS13320, Beckman Coulter, Inc.)

### (Other) Silane Coupling Agent

### 3-glycidoxypropyl trimethoxysilane

As seen from Table 1, comparing the compositions of Examples 1 to 5 and that of Comparative Example 1, each of which contains the allylated phenol novolac resin (D), the bond strength of the latter (the composition of Comparative Example 1) which had not been mixed with a maleimide compound was decreased significantly by a PCT test. In contrast, as for the compositions of Examples 1 to 5 which had been mixed with a maleimide compound, the degradation of bond strength by PCT test was reduced. Further, the compositions have an excellent injection property and can be preferably used in combination with a flip chip bonding. The same is applied to the composition of Example 6 and that of Comparative Example 2. That is, the value of the bond strength of Comparative Example 2 which had not been mixed with a maleimide compound was decreased significantly by a PCT test. In contrast, as for the compositions of Example 6 which had been mixed with a maleimide compound, the degradation of bond strength by PCT test was reduced.

### INDUSTRIAL APPLICABILITY

According to the present invention, there is provided liquid epoxy resin composition for semiconductor encapsulation that can provide a cured material thereof which has excellent adhesiveness to a semiconductor chip surface and has an excellent moisture resistance, and a semiconductor device encapsulated thereby. Therefore, the present invention has a high degree of industrial applicability.

1. A liquid epoxy resin composition for semiconductor encapsulation comprising:
(A) at least one epoxy resin,
(B) at least one imidazole compound, and
(C) at least one maleimide compound.

2. The liquid epoxy resin composition for semiconductor encapsulation according to claim 1, wherein the imidazole compound is in an amount of 0.01 to 10 parts by weight and the maleimide compound is in an amount of 0.1 to 16 parts by weight, based on 100 parts by weight of the epoxy resin.

3. The liquid epoxy resin composition for semiconductor encapsulation according to claim 1, wherein the maleimide compound is at least one compound selected from the group consisting of a monomaleimide compound and a bismaleimide compound.

4. The liquid epoxy resin composition for semiconductor encapsulation according to claim 1, further comprising at least one curing agent (D) selected from the group consisting of a phenolic resin and an acid anhydride.

5. The liquid epoxy resin composition for semiconductor encapsulation according to claim 1, further comprising at least one inorganic filler.

6. The liquid epoxy composition for semiconductor encapsulation according to claim 2, wherein the maleimide compound is at least one compound selected from the group consisting of a monomaleimide compound and a bismaleimide compound.

7. The liquid epoxy composition for semiconductor encapsulation according to claim 2, which further comprises at least one curing agent (D) selected from the group consisting of a phenolic resin and an acid anhydride.

8. The liquid epoxy composition for semiconductor encapsulation according to claim 3, which further comprises at least one curing agent (D) selected from the group consisting of a phenolic resin and an acid anhydride.

9. The liquid epoxy composition for semiconductor encapsulation according to claim 6, which further comprises at least one curing agent (D) selected from the group consisting of a phenolic resin and an acid anhydride.

10. A flip chip semiconductor device comprising a substrate and a semiconductor, wherein the semiconductor is secured to the substrate by a liquid epoxy resin composition according to claim 1.

11. The flip chip semiconductor device according to claim 10, wherein the imidazole compound is in an amount of 0.01 to 10 parts by weight and the maleimide compound is in an amount of 0.1 to 16 parts by weight, based on 100 parts by weight of the epoxy resin.

12. The flip chip semiconductor device according to claim 10, wherein the maleimide compound is at least one compound selected from the group consisting of a monomaleimide compound and a bismaleimide compound.

13. The flip chip semiconductor device according to claim 10, wherein the liquid epoxy resin composition for semiconductor encapsulation further comprises at least one curing agent (D) selected from the group consisting of a phenolic resin and an acid anhydride.

14. The flip chip semiconductor device according to claim 10, wherein the liquid epoxy resin composition for semiconductor encapsulation further comprises at least one inorganic filler.

15. The flip chip semiconductor device according to claim 11, wherein the maleimide compound is at least one compound selected from the group consisting of a monomaleimide compound and a bismaleimide compound.

16. The flip chip semiconductor device according to claim 11, wherein the liquid epoxy resin composition for semiconductor encapsulation further comprises at least one curing agent (D) selected from the group consisting of a phenolic resin and an acid anhydride.

17. The flip chip semiconductor device according to claim 11, wherein the liquid epoxy resin composition for semiconductor encapsulation further comprises at least one inorganic filler.

18. An assembly comprising:
a printed circuit substrate;
a semiconductor die; and
a cured material of a liquid epoxy resin composition according to claim 1, the cured material is positioned between the printed circuit substrate and the semiconductor die, so that the semiconductor die is secured to the printed circuit substrate.
inorganic filler.

19. The assembly according to claim 18, wherein the imidazole compound is in an amount of 0.01 to 10 parts by weight and the maleimide compound is in an amount of 0.1 to 16 parts by weight, based on 100 parts by weight of the epoxy resin.

20. The assembly according to claim 18, wherein the maleimide compound is at least one compound selected from the group consisting of a monomaleimide compound and a bismaleimide compound.
